(19) United States
(12) Patent Application Publication
(10) Pub. No.: US 2010/0195297 A1
(43) Pub. Date: Aug. 5, 2010

(54) ELECTRONIC BALLAST WITH GROUNDING SPACER AND INSULATING FILLER

(76) Inventors: Nobutoshi Matsuzaki, Osaka (JP); Takeshi Goriki, Yawata (JP); Takeshi Kamoi, Kyoto (JP); Akira Yufuku, Himeji (JP)

Correspondence Address: WADDEY & PATTERSON, P.C., 1600 DIVISION STREET, SUITE 500, NASHVILLE, TN, 37203, US

(21) Appl. No.: 12/695,088

(22) Filed: Jan. 27, 2010

(30) Foreign Application Priority Data
Jan. 27, 2009 (JP) 2009-015951

(51) Int. Cl. H05K 5/02

(52) U.S. Cl. 361/758

(57) ABSTRACT

An electronic ballast provides a ballast housing including a circuit board electrically and mechanically connected to the ballast housing by an electrically conductive spacer. The circuit board includes a ground electrode surrounding a clearance hole through which an electrically conductive fastener is inserted into a fastener hole located in the spacer. An insulating filler is disposed in the ballast housing between the housing interior surface and the circuit board. A lighting fixture including an electronic ballast is also provided.

A portion of the disclosure of this patent document contains material that is subject to copyright protection. The copyright owner has no objection to the reproduction of the patent document or the patent disclosure, as it appears in the U.S. Patent and Trademark Office patent file or records, but otherwise reserves all copyright rights whatsoever.

### CROSS-REFERENCES TO RELATED APPLICATIONS

This application claims priority to Japanese National Application 2009-015951, filed Jan. 27, 2009, the content of which is fully incorporated herein.

### BACKGROUND OF THE INVENTION

The present invention relates to an electronic ballast for lighting an gas discharge lamp. More particularly the present invention relates to an electronic ballast for a discharge-type lamp having a grounding spacer and an insulating filler.

Electronic ballasts for discharge-type lamps are known in the art. Such ballasts generally include one or more substrates, or circuit boards, upon which circuit components are mounted. Circuit boards for electronic ballasts are typically positioned inside the ballast housing. It is often desirable in the art to minimize the size of ballast housings to minimize the device profile and to reduce production costs. Thus, it is generally desirable to position ballast circuit boards near the interior ballast housing wall to save space.

A circuit board with electrical components mounted on both sides of a circuit board positioned near a ballast housing interior wall places electrical components in close proximity to the housing wall. When circuit components positioned near the ballast housing wall become charged, a charge potential may develop between the charged component and the housing wall. In some instances, the charge potential may induce an electric discharge between the component and the wall. A charge potential between a charged component and an electrical terminal of a nearby circuit component mounted on the same or an adjacent circuit board may also develop, causing a similar electric discharge. Such an event can cause damage to circuit components, often resulting in device malfunction or failure.

Others in the art have attempted to address these potential problems by positioning one or more spacers between the circuit board and the housing wall to create a gap between the circuit board and the electrical components extending from the side of the circuit board facing the housing wall. By separating charged components from the interior housing wall by a sufficient distance, the likelihood of an electric discharge between a component and the housing wall can be reduced. However, increasing the distance between the circuit board and the ballast housing wall undesirably increases the overall device profile.

Others have attempted to prevent electric discharge between charged circuit components and ballast housing walls by forming holes in the circuit board and pouring an electrically insulating liquid filler material through the holes to fill the gap between the prior art circuit board and the wall. The insulating filler forms a shield between the circuit board and the wall, thereby preventing undesirable electric discharge and allowing a reduction of the gap distance between the circuit board and the housing wall for achieving reduced device profile. However, pouring insulating filler into the gap between the prior art circuit board and the housing wall can result in the formation of gaseous bubbles in the filler. A bubble trapped between a charged component and either the ballast housing wall or an adjacent component or component terminal provides a path for component-damaging electric discharge.

Additionally, a circuit board positioned near a housing wall can shift relative to the wall, causing variation in the gap between circuit components and the wall. Gap variations can increase the potential for electric discharge. Others have attempted to use spacers in combination with an insulating filler to prevent circuit board shifting. This prior art approach includes pouring a liquid insulating filler between the circuit board and the housing wall to a depth greater than the height of the circuit board. The filler encapsulates the circuit board in a hardened medium and adheres the circuit board to the housing wall. However, the insulating filler may become weak or deteriorate over time, causing a reduction in the adhesiveness between the filler and the circuit board or the filler and the wall, resulting in detrimental movement of the circuit board relative to the housing.

Still others have attempted to address the problem of electric discharge by positioning a layer of insulating paper between the interior surface of the ballast housing and the insulating filler. The insulating paper aims to prevent discharge between the charged part and the housing wall. However, the layer of insulating paper decreases the thermal conductivity of the ballast housing and reduces heat dissipation through the housing wall, thereby raising the internal ballast housing temperature to an undesirable level, potentially damaging circuit components or causing fire.

Additionally, in one type of discharge lamp, a high voltage is necessary to initially light, or start, the lamp. The high voltage can become unstable, causing fluctuations in circuit performance and causing component or device failure. Others have attempted to stabilize a starting high voltage by mechanically and electrically connecting an earth electrode, or ground connector, on the circuit board to the ballast housing wall using an electrically conductive wire and a screw connector. However, the use of a wire conductor can adversely affect performance of the ballast due to, among other things, inconsistencies between individual wires including differences in the ways individual wires are drawn.

What is needed then is an electronic ballast for a lighting device having a circuit board electrically insulated from the ballast housing wall by an insulating filler and electrically grounded to the housing wall through a spacer having an internal electrical terminal.

### BRIEF SUMMARY OF THE INVENTION

The present invention provides a discharge lamp lighting device, or electronic ballast, including a ballast housing defining an interior cavity and having a first interior surface substantially facing the interior cavity. The ballast includes a circuit board positioned in the interior cavity oriented substantially parallel to the first interior surface and including an outer edge defining a circuit board perimeter having substantially the same outer shape as the first interior surface. The circuit board is substantially flat and includes a first side facing substantially toward the first interior surface and a second side facing substantially away from the first interior surface. A ground electrode is positioned on one side of the circuit board.

A plurality of electronic circuit components are mounted on the circuit board, and one of the plurality of electronic circuit components has a distal end extending away from the first side of the circuit board toward the first interior surface. The distal end defines a maximum component distance from the first side of the circuit board. An insulating filler is disposed between the circuit board and the ballast housing. In one embodiment, the insulating filler extends from the first interior surface to the distal end of the electronic circuit component. An electrically conductive spacer includes a first end connected to the first interior surface of the housing and includes a second end contacting the first side of the circuit board. The second end of the spacer defines a fastener hole therein. The circuit board defines a clearance hole extending from the first side to the second side, and the clearance hole overlaps the fastener hole. An electrically conductive fastener is inserted through the clearance hole into the fastener hole so that the fastener contacts both the ground electrode and the spacer.

Another embodiment of the present invention provides a lighting fixture apparatus for providing illumination. The lighting fixture includes a lamp housing shaped for receiving the lamp and an electronic ballast electrically connected to the lamp housing. The electronic ballast includes a ballast housing defining an internal cavity and having a first interior surface. The electronic ballast also includes a circuit board having first and second sides positioned in the internal cavity. The first side of the circuit board faces substantially toward the first interior surface and the circuit board defines at least one clearance hole extending from the first side to the second side and includes a ground electrode at least partially surrounding the clearance hole. The electronic ballast also includes an electrically conductive spacer having a first end connected to the ballast housing and having a second end abutting the first side of the circuit board, the second end defining a fastener engagement hole overlapping the clearance hole. The electronic ballast also includes a metal fastener extending through the clearance hole into the fastener engagement hole. The metal fastener comprises an electrically conductive material and engages in electrical contact with both the ground electrode and the spacer.

### BRIEF DESCRIPTION OF THE DRAWINGS

FIG. 1 is a side view of one embodiment of an electronic ballast in accordance with the present invention.

FIG. 2A illustrates a detail cross section view of one embodiment of an electronic ballast in accordance with the present invention.

FIG. 2B illustrates a top view of one embodiment of an electronic ballast in accordance with the present invention.

FIG. 3A illustrates a plan view of one embodiment of an electronic ballast in accordance with the present invention.

FIG. 3B illustrates a plan view of one embodiment of an electronic ballast in accordance with the present invention.

FIG. 4A illustrates a plan view of the embodiment of the electronic ballast shown in FIG. 3B.

FIG. 4B illustrates a partial cross-section elevation view of one embodiment of an electronic ballast in accordance with the present invention.

FIG. 5 shows a detail partial cross section view of one embodiment of an electronic ballast in accordance with the present invention.

FIG. 6A illustrates a detail partial cross section view of one embodiment of an electronic ballast in accordance with the present invention.

FIG. 6B illustrates a detail partial cross section view of the electronic ballast of FIG. 6A.

FIG. 7A illustrates a detail partial cross section of an alternative embodiment of an electronic ballast in accordance with the present invention.

FIG. 7B illustrates a detail partial cross section of an alternative embodiment of an electronic ballast in accordance with the present invention.

FIG. 8 shows a cross section of one embodiment of an electronic ballast in accordance with the present invention.

FIG. 9 shows a partial plan view of one embodiment of an electronic ballast in accordance with the present invention.

FIG. 10 shows a partial plan view of one embodiment of an electronic ballast in accordance with the present invention.

FIG. 11A shows one embodiment of a lighting fixture including an electronic ballast in accordance with the present invention.

FIG. 11B shows another embodiment of a lighting fixture including an electronic ballast in accordance with the present invention.

FIG. 11C illustrates another embodiment of a lighting fixture including an electronic ballast in accordance with the present invention.

### DETAILED DESCRIPTION OF THE INVENTION

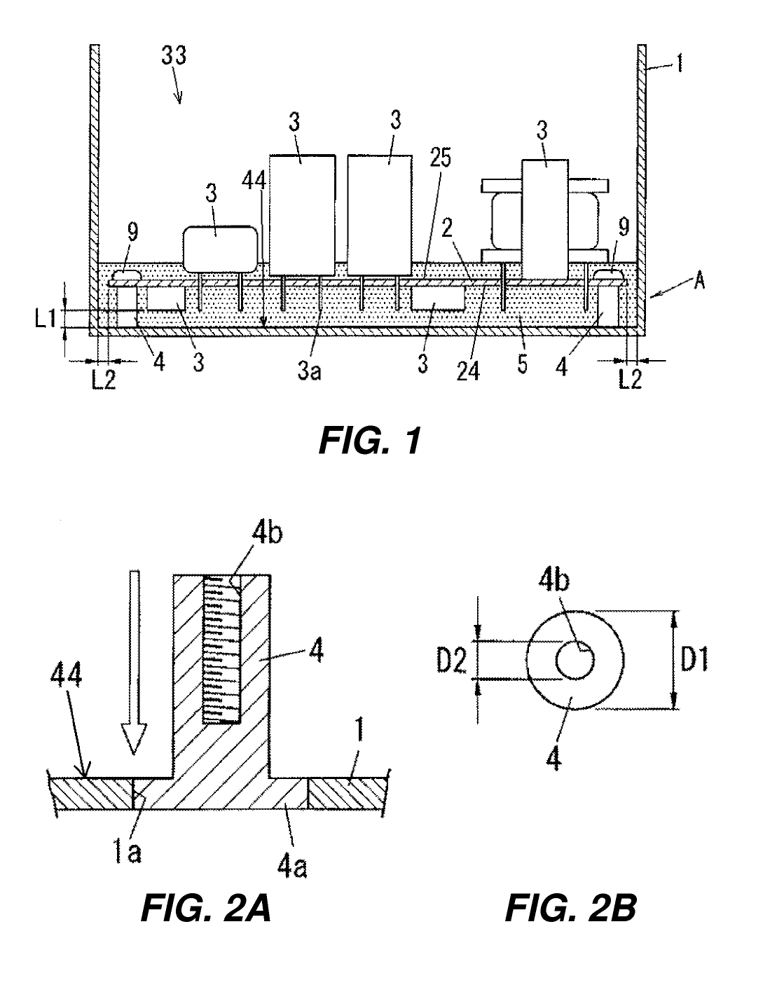

Referring to FIG. 1, one embodiment of a discharge lamp lighting device, or ballast, A is generally shown. The ballast A includes a ballast housing 1. In one embodiment, the ballast housing 1 is metal and is formed into the shape of a rectangular box. The ballast housing defines an interior cavity 33 and includes a first interior surface 44 facing into the cavity 33.

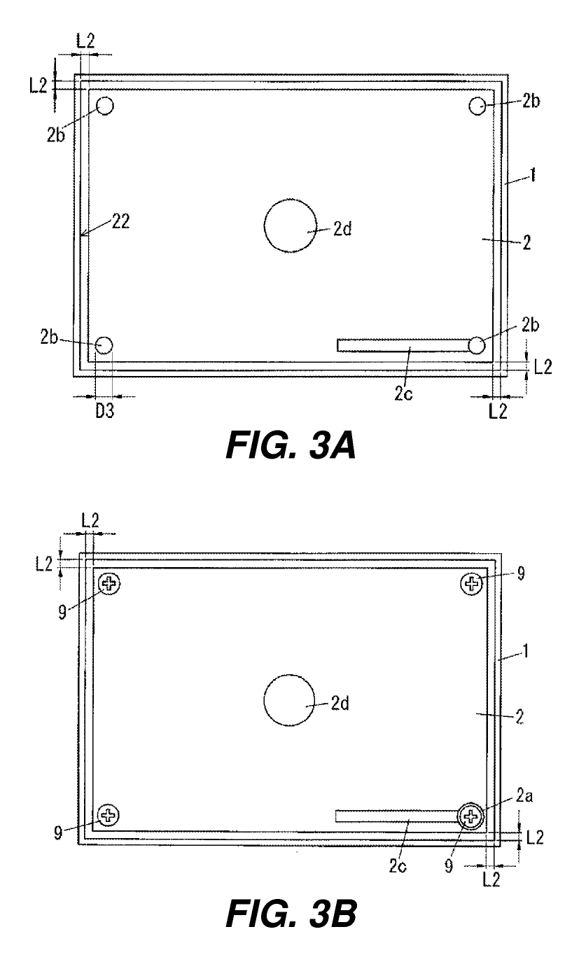

A substrate, or circuit board, 2 is housed in the ballast housing 1. In one embodiment, the circuit board 2 is substantially planar, substantially rectangular, and is oriented substantially parallel to the first interior surface 44 of the ballast housing 1. The circuit board 2 may have the same shape as the first interior surface 44. The circuit board 2 includes a first side 24 facing substantially toward the first interior surface 44 and a second side 25 substantially facing away from the first interior surface 44. In one embodiment, an earth, or ground, pattern 2c forms an earth, or ground, electrode 2a on the circuit board 2, as seen in FIGS. 3A and 3B. The ground pattern 2c can become a ground potential during operation of the circuit. In one embodiment, the ground electrode 2a is printed directly onto the second side 25 of the circuit board 2.

A plurality of electronic circuit components 3 are mounted on the circuit board 2. The circuit components can be mounted on either the first side 24 or second side 25 of the circuit board 2. In one embodiment, the electronic circuit components 3 may be electrically interconnected on the circuit board 2 for powering or regulating a gas-discharge lamp.

Referring now to FIGS. 2A and 2B, in one embodiment a substantially cylindrical spacer 4 is positioned between the circuit board 2 and the first interior surface 44 of the ballast housing 1. In one embodiment, the spacer 4 is made of an electrically conductive material and includes a brim, or circumferential flange 4a, projecting outward from its lower end. A fastener hole 4b for receiving a fastener is drilled from its upper end face in an axial direction. In one embodiment, the circumferential flange 4a is press-fit into a spacer mounting hole 1a formed in the first interior surface 44 of the ballast housing 1. The spacer 4 has an outer diameter D1, and the hole 4b has a diameter D2, as seen in FIG. 2B.

Further, as shown in FIG. 3A, one or more clearance holes 2b for receiving fasteners 9 are formed near the four corners of the circuit board 2. Each clearance hole 2b has a diameter D3 that is smaller than the diameter D1 of the spacer 4 and is larger than the diameter D2 of the hole 4b. The circuit board 2 is fixed to each of the electrically conductive spacers 4 by a fastener 9 being inserted through each of the through holes 2b and engaging one of the holes 4b in the spacer 4.

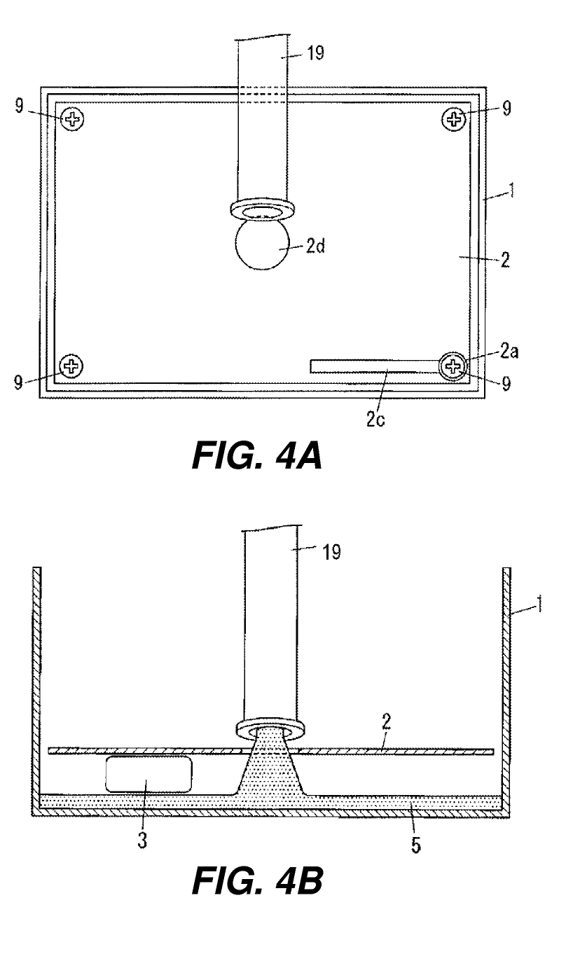

In one embodiment, an insulating filler 5 is positioned in the ballast housing 1 at least partially between the circuit board 2 and the first interior surface 44. As shown in FIGS. 4A and 4B, the insulating filler 5 can be filled up between the first interior surface 44 of the ballast housing 1 to at least the first side 24 of the circuit board 2 from a filling machine 19 through a filling hole 2d formed substantially in the center of the circuit board 2. In one embodiment, the insulating filler 5 is filled up to such a height as to cover the whole of lead wires 3a of electronic components 3 mounted on the second side 25 of the circuit board 2, as seen in FIG. 1. In another embodiment, one of the plurality of circuit components 3 defines a maximum component distance from the second side 25 of the circuit board 2, and the insulating filler 5 extends from the first interior surface 44 to a height above the tallest circuit component 3.

Referring now to FIG. 3A, in one embodiment of an electronic ballast in accordance with the present invention, the second side 25 of the circuit board 2 includes an earth, or ground, pattern 2c. The ground pattern 2c may be etched or printed onto to the circuit board 2. One of the clearance holes 2b defined in the respective four corners of the circuit board 2 is formed on the earth, or ground, pattern 2c on the second side 25 of the circuit board 2. The ground pattern 2c is shaped to at least partially surround the circumference of the clearance hole 2b. The region of the ground pattern 2c surrounding the clearance hole 2b can be referred to as an earth, or ground, electrode 2a. The ground electrode 2a is electrically connected to the electrically conductive spacer 4 through an electrically conductive fastener 9 inserted into the fastener hole 4b on the spacer 4 through the clearance hole 2b. In one embodiment, the electrically conductive fastener 9 can be a metal screw. The ground electrode 2a is thus electrically connected to the ballast housing 1 through the spacer 4 and the fastener 9, allowing stabilization of the ground potential.

Therefore, by sandwiching the circuit board 2 between the spacer 4 and the fastener 9, it is possible to mechanically secure the circuit board 2 without relying on the adhesive nature of the insulating filler. Also, by electrically connecting the ground pattern 2c to the ballast housing 1 through the spacer 4 and fastener 9, it is possible to stabilize the circuit so that a variation in ballast performance (including EMI noise) can be prevented.

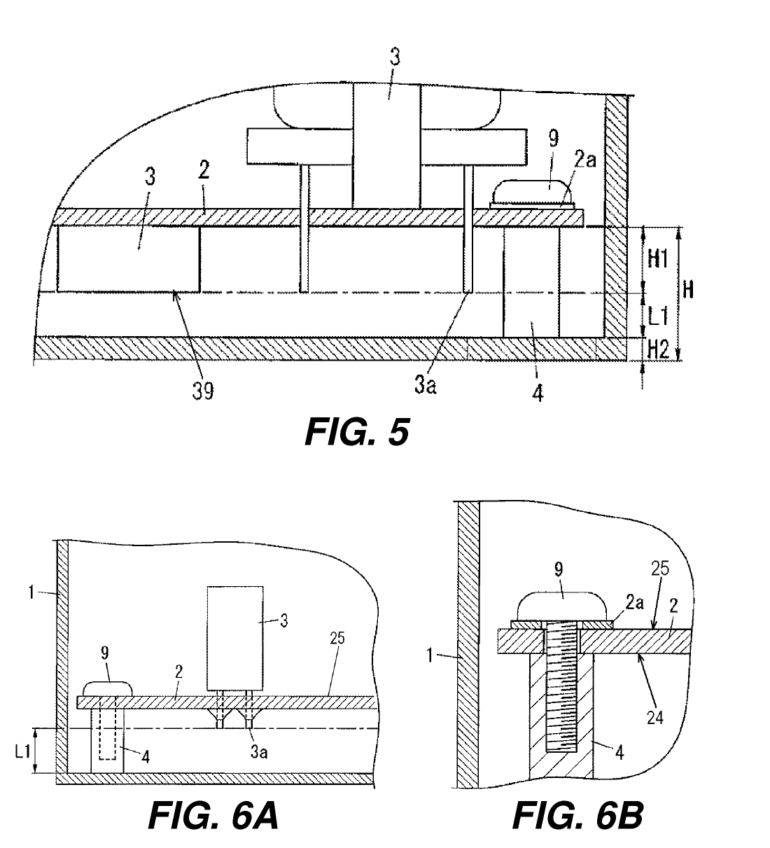

Referring now to FIG. 5, one embodiment in accordance with the present invention includes insertion terminal lead wires 3a extending from the first side 24 of the circuit board 2. One of the plurality of components 3 includes a terminal lead wire 3a that projects a maximum component distance from the first side 24 of the circuit board 2, denoted by the distance H1. A first spatial distance, L1 extends from the end of the lead wire 3a to the first interior surface 44. The thickness of the metal case is denoted L2. Thus, the height of the spacer 4 is H=H1+L1+H2.

The insulating filler 5 may include a minimum insulation performance dimension above which insulation performance and fluidity of the insulation material are guaranteed. In one embodiment, the insulation performance dimension of the insulating filler 5 is 1 mm. By setting the first spatial distance L1 as greater than or equal to 1 mm, the insulating filler 5 is filled up without leaving a gap between the first side 24 of the circuit board 2 and the first interior surface 44 of the ballast housing 1 without its fluidity being inhibited.

Referring again to FIG. 3A, in one embodiment in accordance with the present invention, the ballast housing 1 includes a second interior surface 22 oriented substantially perpendicular to the plane of orientation of the circuit board 2. A peripheral distance, or second spatial distance, L2 extends between the outer edge of the circuit board 2 and the second interior surface 22, as seen in FIG. 3A. The second spatial distance L2 can be equal to or greater than the insulation performance dimension of the insulating filler 5 to allow fluidity and efficient insulation of the insulating filler 5. In one embodiment, the second spatial distance L2 is greater than or equal to 1 mm where the insulation performance dimension of the insulating filler 5 is equal to 1 mm. In this way, the second spatial distance L2 is also set up similarly as the first spatial distance L1, whereby it is possible to secure the insulation between a charged section or component including the lead wires 3a of the electronic components 3 mounted on the circuit board 2, a wiring pattern formed on the circuit board 2, etc., and the second interior surface 22 of the ballast housing 1, and it is possible to secure the fluidity of the insulating filler 5.

In one embodiment, the plurality of electronic components 3 include both insertion terminal components and surface mount components. In one embodiment, only surface mount components are mounted on the first side 24 of the circuit board 2, and only insertion terminal components are mounted on the second side 25 of the circuit board 2. In this one of several embodiments in accordance with the present invention, flow soldering of the first side 24 of the circuit board 2 may be used to simultaneously secure the surface mount and insertion terminal components to the circuit board 2. Referring now to FIGS. 6A and 6B, in this embodiment, the ground electrode 2a is positioned on the second side 25 of the circuit board. This embodiment prevents solder from the flow soldering process from adhering to the ground pattern 2c on the second side 25 of the circuit board 2, allowing the bearing surface of the fastener 9 to abut directly against the ground electrode 2a. This embodiment further prevents solder from the flow soldering process from adhering to the first side 24 of the circuit board 2 in the vicinity of the clearance hole 2b, allowing the spacer 4 to abut directly against the first side 24 of the circuit board 2. This embodiment further allows stabilization of the first spatial distance L1 by preventing the positioning of material between either the fastener 9 and the ground electrode 2b or the spacer 4 and the circuit board 2.

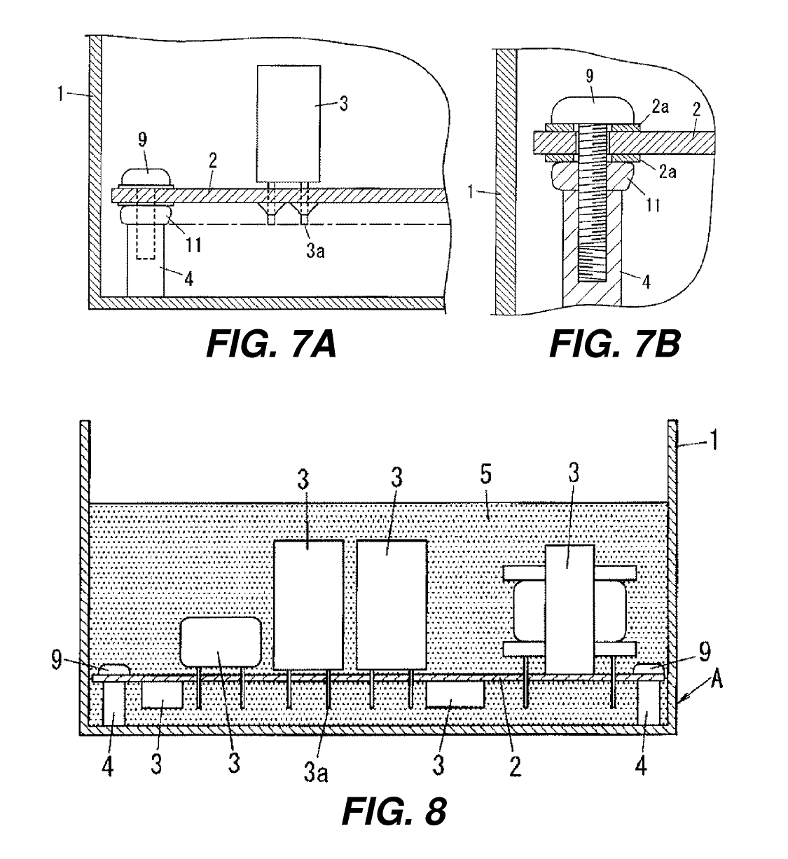

Referring now to FIGS. 7A and 7B, in the case where the ground electrode 2a is provided on the first side 24 of the circuit board 2, solder 11 adheres to the ground pattern 2c on the first side 24 of the circuit board 2 in the flow soldering process at the time of manufacture of the circuit board 2. If one location on the ground pattern 2c is used as the ground electrode 2a, the solder 11 will intervene between the ground electrode 2a and the spacer 4. Then, because the solder 11 that adheres to the ground pattern 2c by the flow soldering causes a variation in height, the second side 24 of the circuit board 2 and the first interior surface 44 of the ballast housing 1 may be not stabilized and the first spatial distance L1 may vary. Moreover, it is possible that if the layer of solder 11 becomes thin by age deterioration, a gap will occur between the circuit board 2 and the spacer 4, and the contact pressure between the circuit board 2 and the fastener 9 will decrease to loosen the fastener 9, causing poor electrical contact between the ground electrode 2b and the fastener 9.

Referring now to FIG. 8, in one embodiment in accordance with the present invention, the insulating filler 5 may be filled up to such a height as to cover all electronic components 3 mounted on the circuit board 2. In this embodiment, one of the plurality of circuit components 3 extends a maximum component distance above the second side 25 of the circuit board 2. The insulating filler 5 is poured to a depth greater than the maximum component distance above the second side 25 of the circuit board 2. This configuration can prevent moisture such as humidity from contacting the circuit components 3, and provides insulation of all the components.

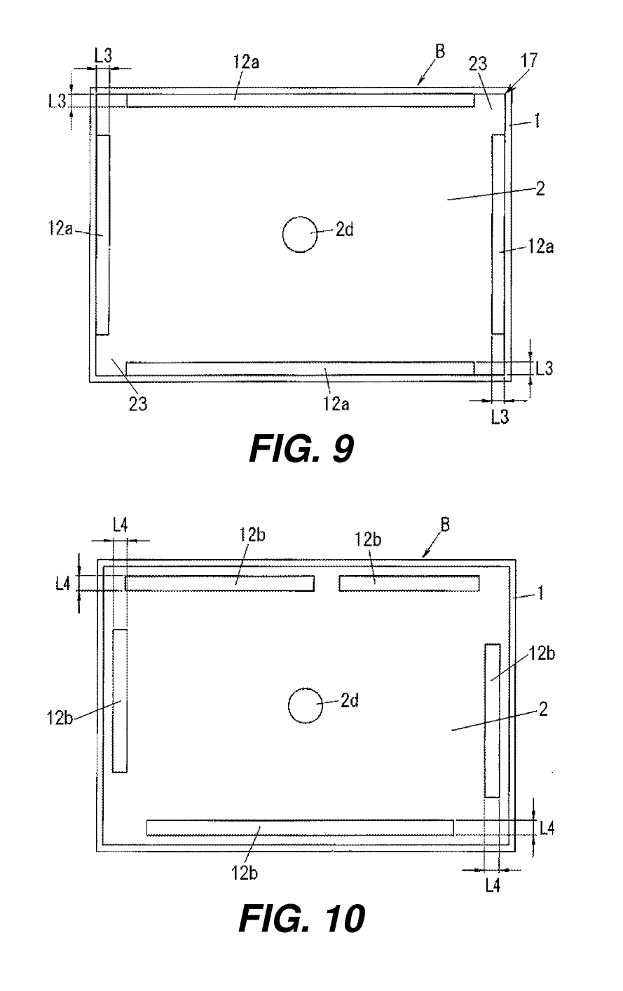

Referring now to FIG. 9, one embodiment of a discharge lamp lighting device, or electronic ballast, B in accordance with the present invention is shown. In this embodiment, the circuit board 2 includes an outer dimension substantially the same as the inner dimension of the ballast housing 1. In this embodiment, the circuit board 2 has a substantially rectangular shape. The ballast housing 1 defines a plurality of interior corners 17. An outer corner 23 of the circuit board 2 extends into and fills each interior corner 17 of the ballast housing 1. The circuit board 2 includes one or more notched recesses 12a on the outer edge of the circuit board 2 between adjacent outer corners 23.

The notched recess 12a extends a length L3 into the edge of the circuit board 2. In one embodiment, the distance L3 is chosen to be equal to or greater than the insulation performance dimension to ensure fluidity and insulation performance of the insulating filler 5. In one embodiment, the dimension L3 is greater than 1 mm.

Referring now to FIG. 10, in another embodiment of an electronic ballast B, the circuit board 2 includes an outer dimension substantially equal to the interior dimension of the ballast housing 1. The circuit board 2 includes one or more elongated slits 12b having a width L4 positioned along respective sides of the circuit board 2. Where the distance L4 is greater than or equal to the insulation performance dimension of the insulating filler 5, a desired insulating filler liquidity and insulation performance can be attained. In one embodiment, the distance L4 is greater than or equal to 1 mm.

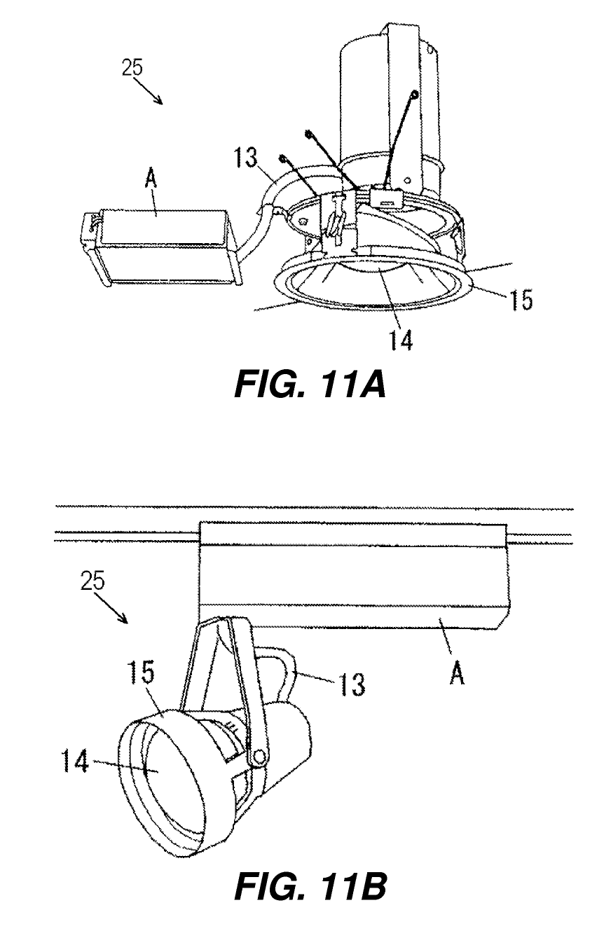

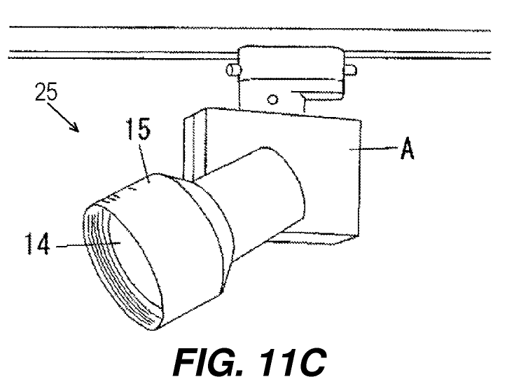

Referring now to FIGS. 11A-11C, one embodiment of a lamp or illumination fixture 25 in accordance with the present invention is shown. The illumination fixture 25 is equipped with the discharge lamp lighting device, or electronic ballast A. In another embodiment, the fixture 25 of FIGS. 11A-11C may include an electronic ballast B, shown in FIG. 10, or other types of electronic ballasts in accordance with the present invention. FIG. 11A shows a downlight to which the electronic ballast A is applied, and FIGS. 11A and 11B show different embodiments of spotlights to which an electronic ballast A in accordance with the present invention is applied.

The illumination fixture 25 generally includes a ballast A and a lamp housing 15 shaped for receiving a lamp 14. In one embodiment, the fixture 25 is a adapted for receiving a gas-discharge lamp. In one embodiment a cable 13 electrically connects the electronic ballast A to the lamp housing 15, as seen in FIGS. 11A and 11B. Alternately, the lamp housing 15 may be directly connected to the electronic ballast A.

Thus, although there have been described particular embodiments of the present invention of a new and useful Electronic Ballast with Grounding Spacer and Insulating Filler, it is not intended that such references be construed as limitations upon the scope of this invention except as set forth in the following claims.

What is claimed is:

1. An electronic ballast apparatus, comprising:
a ballast housing defining a interior cavity and having a first interior surface substantially facing the interior cavity;
a circuit board positioned in the interior cavity oriented substantially parallel to the first interior surface, the circuit board being substantially flat and including a first side facing substantially toward the first interior surface and a second side facing substantially away from the first interior surface;
a ground electrode positioned on the circuit board;
a plurality of circuit components mounted on the circuit board, one of the plurality of circuit components having a distal end extending away from the first side of the circuit board toward the first interior surface, the distal end defining a maximum component distance from the first side of the circuit board;
an insulating filler disposed between the circuit board and the ballast housing extending from the first interior surface to the distal end of the electronic circuit component;
an electrically conductive spacer including a first end connected to the first interior surface of the housing and a second end contacting the first side of the circuit board, the second end defining a fastener hole therein;
the circuit board defining a clearance hole extending from the first side to the second side, the clearance hole overlapping the fastener hole; and
an electrically conductive fastener inserted through the clearance hole into the fastener hole so that the fastener contacts both the ground electrode and the spacer.

2. The apparatus of claim 1, wherein the insulating filler extends at least from the first interior surface of the ballast housing to the first side of the circuit board.

3. The apparatus of claim 2, further comprising:
one of the plurality of circuit components defining a maximum component distance from the second side of the circuit board; and
wherein the insulating filler extends from the first interior surface of the ballast housing to a depth greater than the maximum component distance from the second side of the circuit board.

4. The apparatus of claim 1, wherein:
the first interior surface defines an inner dimension of the ballast housing;
the circuit board defines an outer dimension substantially coextensive with the inner dimension of the ballast housing; and
the circuit board defines a notched recess on the outer edge of the circuit board.

5. The apparatus of claim 1, wherein:
the circuit board includes an outer dimension substantially equal to the inner dimension of the ballast housing; and
the circuit board comprises elongated slots extending from the first side to the second side.

6. The apparatus of claim 1, wherein the ground electrode is printed directly onto the second side of the circuit board.

7. The apparatus of claim 1, wherein:
the insulating filler includes a minimum insulation performance dimension; and
the maximum component distance from the first side of the circuit board is greater than the minimum insulation performance dimension.

8. The apparatus of claim 1, wherein:
the ballast housing includes a second interior surface oriented substantially perpendicular to the circuit board;
the circuit board defines a peripheral distance between the outer edge of the circuit board and the second interior surface, the peripheral distance extending in a direction substantially parallel to the circuit board;
the insulating filler has a minimum insulation performance dimension; and
the peripheral distance is greater than the minimum insulation performance dimension.

9. A discharge lamp lighting device, comprising:
a ballast housing, the ballast housing defining an interior cavity and having a first interior surface;
a circuit board positioned in the interior cavity, the circuit board having a substantially planar shape oriented substantially parallel to the first interior surface, the circuit board including a plurality of electronic components mounted thereon, the circuit board including a first side facing substantially toward the interior surface and a second side facing substantially away from the first interior surface, one of the plurality of electronic components having a distal end extending a maximum distance from the first side toward the first interior surface, the circuit board defining a clearance hole extending from the first side to the second side;
a ground electrode comprising an electrically conductive material positioned on the circuit board, the ground electrode at least partially surrounding the clearance hole;
an insulating filler disposed in the cavity between the first interior surface of the housing and the distal end of the one of the plurality of electronic components;
an electrically conductive spacer positioned between the circuit board and the ballast housing and having a first end connected to the first interior surface of the ballast housing and a second end abutting the first side of the circuit board, the second end defining a fastener hole; and
an electrically conductive fastener extending through the clearance hole into the fastener hole, the fastener engaging in electrical contact with both the ground electrode and the spacer.

11. The device of claim 10, wherein the ground electrode is positioned only on the second side of the circuit board.

12. The device of claim 11, wherein the ground electrode is printed directly onto the circuit board.

13. The device of claim 10, wherein the insulating filler extends from the first interior surface of the ballast housing to the first side of the circuit board.

14. The device of claim 10, wherein the insulating filler extends from the first interior surface of the ballast housing to the second side of the circuit board.

15. The device of claim 10, wherein:
one of the plurality of circuit components defines a maximum component distance from the second side of the circuit board; and
the insulating filler has extends greater than the distance from first interior surface of the ballast housing to the maximum component distance from the second side of the circuit board.

16. The device of claim 10, wherein:
the ballast housing defines a plurality of interior housing corners oriented substantially perpendicular to the first interior surface;
the circuit board defines a plurality of outer corners extending substantially coextensively with the interior corners; and
the circuit board defines a notched recess on the outer edge of the circuit board between adjacent outside corners.

17. The device of claim 10, wherein:
the first interior surface defines an inner dimension of the ballast housing;
the circuit board includes an outer edge defining an outer dimension of the circuit board, the outer dimension of the circuit board being substantially equal to the inner dimension of the ballast housing; and
the circuit board comprises an elongate clearance slot extending through the circuit board from the first side to the second side.

18. The apparatus of claim 10, wherein the circuit board further comprises a filling hole shaped for injecting insulating filler located substantially at the center of the circuit board.

19. A lighting fixture apparatus for providing illumination using a lamp, the apparatus comprising:
a lamp housing shaped for receiving the lamp; and
an electronic ballast electrically connected to the lamp housing, the electronic ballast comprising:
a ballast housing defining an internal cavity and having a first interior surface;
a circuit board having first and second sides, the first side facing substantially toward the first interior surface, the circuit board defining at least one clearance hole extending from the first side to the second side;
a ground electrode comprising an electrically conductive material at least partially surrounding the clearance hole;
an electrically conductive spacer having a first end electrically and mechanically secured to the ballast housing and having a second end abutting the first side of the circuit board, the second end defining a fastener engagement hole overlapping the clearance hole; and
a metal fastener extending through the clearance hole into the fastener hole, the metal fastener comprising an electrically conductive material and engaging in electrical contact with both the ground electrode and the spacer.

20. The apparatus of claim 19, wherein the ground electrode is printed directly only onto the second side of the circuit board.
